(19) United States
(12) Patent Application Publication
(10) Pub. No.: US 2017/0162570 A1
(43) Pub. Date: Jun. 8, 2017

(54) Complementary Transistor Pair Comprising Field Effect Transistor Having Metal Oxide Channel Layer

(71) Applicant: Advanced Device Research Inc., Taipei City (TW)

(72) Inventors: Chen-Wei Shih, Tainan City (TW); Albert Chin, Kaohsiung City (TW)

(21) Appl. No.: 14/956,771

(22) Filed: Dec. 2, 2015

(51) Int. Cl. H01L 27/092; H01L 29/51; H01L 29/49; H01L 29/24; H01L 27/06; H01L 29/16; H01L 29/22; H01L 27/088; H01L 29/423

(52) U.S. Cl. CPC H01L 27/0922; H01L 27/0924; H01L 27/0883; H01L 29/513; H01L 29/4966; H01L 29/517; H01L 29/42364; H01L 29/42376; H01L 27/0688; H01L 29/16; H01L 29/22; H01L 29/24

(57) ABSTRACT

A complementary transistor pair with an n-type enhancement-mode field effect transistor and a p-type field effect transistor is disclosed. The n-type enhancement-mode field effect transistor uses a metal oxide channel layer having a material selected from SnO₂, ITO, ZnO, SnO₂ and In₂O₃ while the p-type field effect transistor uses a germanium-containing channel layer.

### FIELD OF THE DISCLOSURE

The present invention relates to complementary transistor pair comprising a field effect transistor having metal oxide channel layer and three-dimensional integrated scheme comprising such complementary transistor pair.

### BACKGROUND OF THE INVENTION

In the past, the size of transistor has been scaled down dramatically to provide faster and smaller integrated circuits. According to Moore's law, every two years transistors should be scaled down and move to the next generation (node). However, the shrinkage pace is slowing down recently due to limits by the law of physics.

For a long time and for many occasions, searching and developing new materials allows the semiconductor industry to go beyond limits without size shrinkage. A well-recognized case is to replace silicon dioxide, a commonly used gate dielectric layer, with a high-k (high dielectric constant) material. By doing so, thickness of the gate dielectric layer can be maintain (hence free from electron tunneling issues) while gaining good performance for the transistor.

Higher mobility is another focus in this field. Scientist found a technology to either stretch or compress inter-atomic distance between atoms within a transistor channel. By doing so, the mobility of electrons or holes can be increased and performance of the transistor can be boosted. However, such technology can only provided limited improvement and brings side effects such as more process steps, dislocation defects, etc.

The semiconductor industry needs a new channel material capable of providing high mobility and easy to be integrated with other elements of transistors.

### SUMMARY OF THE INVENTION

An aspect of the present invention provides a complementary transistor pair comprising an n-type enhancement-mode field effect transistor and a p-type field effect transistor. The n-type enhancement-mode field effect transistor uses a metal oxide channel layer comprising a material selected from SnO₂, ITO, ZnO, SnO₂ and In₂O₃ while the p-type field effect transistor uses a germanium-containing channel layer.

Another aspect of the present invention provides a three-dimensional integrated scheme comprising multiple device layers stacked vertically and electrically connected. Each of the multiple device layers comprises an n-type enhancement-mode field effect transistor and a p-type field effect transistor. The n-type enhancement-mode field effect transistor uses a metal oxide channel layer comprising a material selected from SnO₂, ITO, ZnO, SnO₂ and In₂O₃ while the p-type field effect transistor uses a germanium-containing channel layer.

According to one embodiment of the present invention, the metal oxide channel layer is at amorphous state or nano-crystalline state.

According to one embodiment of the present invention, the metal oxide channel layer has a thickness less than a threshold value. With the thickness less than the threshold value the metal oxide channel layer exhibits pinch-off behavior in transfer characteristics and has a mobility trend without saturation under positive operational voltage. In some cases, the threshold value is 10 nm.

According to one embodiment of the present invention, the metal oxide channel layer has a conductivity less than an upper threshold value to have proper pinch off behavior in transfer characteristics and more than a lower threshold value to be semi-conductive. In some cases, the upper threshold value is 10⁵ S/m and the lower threshold value is 1 S/m.

According to one embodiment of the present invention, the n-type enhancement-mode field effect transistor and the p-type field effect transistor are both fin-type field effect transistors.

According to one embodiment of the present invention, the n-type enhancement-mode field effect transistor and the p-type field effect transistor are both planar field effect transistors. In some cases, the planar field effect transistors may comprise a high-k dielectric layer and a metal gate. The high-k dielectric layer may be linear shaped or U-shaped. The metal gate may comprise a linear shaped or U-shaped work function layer.

### BRIEF DESCRIPTION OF THE DRAWINGS

FIGS. 1-2 are schematic cross-sectional views illustrating an exemplary complementary transistor pair according to an embodiment of the present invention and method for manufacturing such transistor pair.

FIGS. 1, 3A and 3B are schematic cross-sectional views illustrating an exemplary complementary transistor pair according to another embodiment of the present invention and method for manufacturing such transistor pair.

FIGS. 1 and 4A-4D are schematic cross-sectional views illustrating an exemplary complementary transistor pair according to yet another embodiment of the present invention and method for manufacturing such transistor pair.

FIG. 5 is a schematic cross-sectional view illustrating an exemplary complementary transistor pair according to yet another embodiment of the present invention, wherein the high-k (high dielectric constant) gate dielectric layers formed in gate trenches are U-shaped in stead of linear shaped.

FIGS. 6A-6B are schematic cross-sectional views illustrating an exemplary complementary fin-type transistor pair according to an embodiment of the present invention and method for manufacturing such fin-type transistor pair.

FIGS. 7A-7B are schematic cross-sectional views illustrating an exemplary complementary fin-type transistor pair according to another embodiment of the present invention and method for manufacturing such fin-type transistor pair.

FIG. 8 is a schematic cross-sectional view illustrating a three-dimensional integrated scheme according to an embodiment of the present invention.

### DESCRIPTION OF THE PREFERRED EMBODIMENTS

The following descriptions illustrate embodiments of the present invention in detail. All the components, sub-portions, structures, materials and arrangements therein can be arbitrarily combined in any sequence despite their belonging to different embodiments and having different sequence originally. All these combinations are considered to fall into the scope of the present invention which is defined by the appended claims.

There are a lot of embodiments and figures within this application. To avoid confusions, similar components are designated by the same or similar numbers. To simplify figures, repetitive components are only marked once. Furthermore, in the detailed top views or cross-sectional views only a partial layout is shown for illustration but a person skilled in the art can understand a complete layout may comprise a plurality of the partial layouts and more.

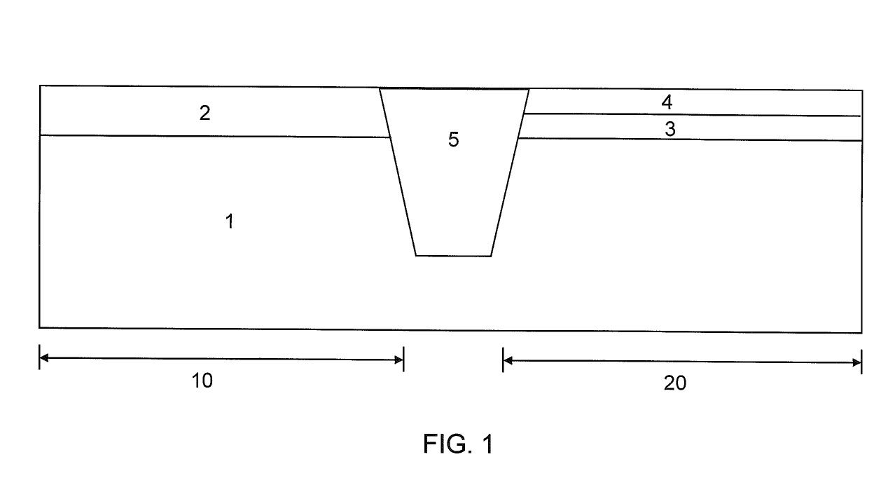

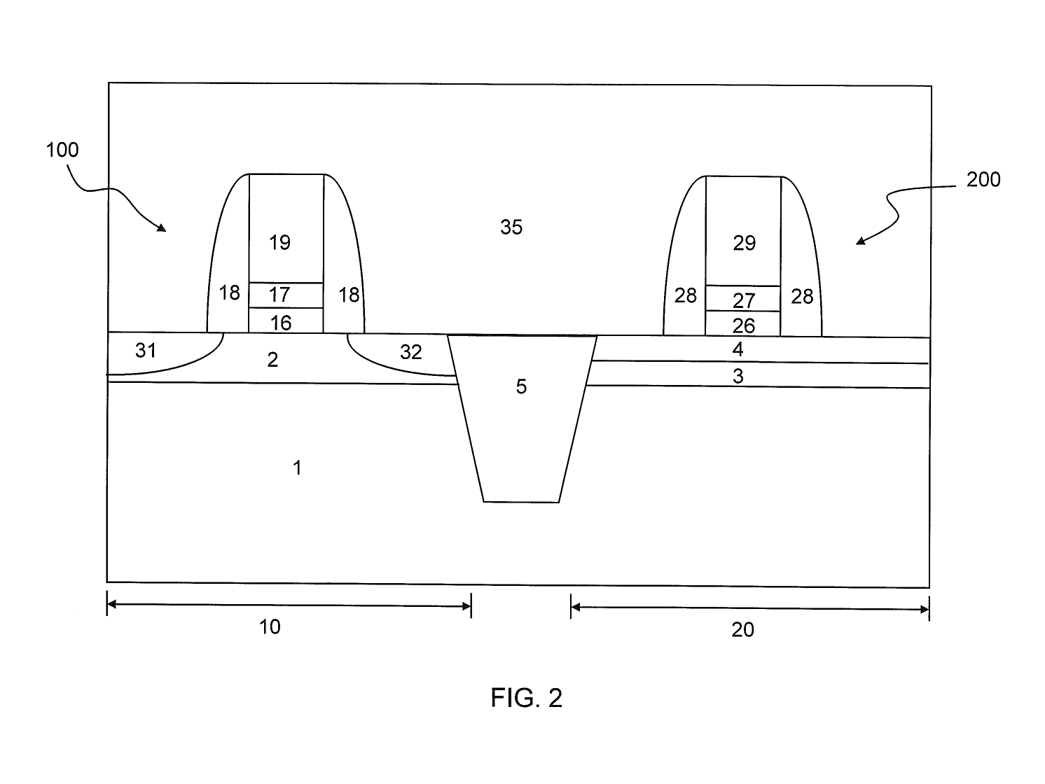

Now a basic field effect transistor of the present invention and its electrical properties are discussed in conjunction with FIGS. 1-2. This basic field effect transistor can be used in a memory array such as a dynamic random access memory (DRAM) array, a 6-T flash memory array, a magnetic random access memory (MRAM) array, a pheriphery circuitry of a memory array, a central processing unit, a microcontroller, a field programmable gate array (FPGA), or any circuitry using complementary transistor pairs. FIGS. 1-2 are schematic cross-sectional views illustrating an exemplary complementary transistor pair comprising transistors 100 and 200 according to an embodiment of the present invention and method for manufacturing such transistor pair. The term “complementary transistor pair” used here means a combination of an n-type field effect transistor (n-type FET) especially an n-type enhancement-mode FET and a p-type field effect transistor (p-type FET). The term “n-type field effect transistor (n-type FET)” used here means the majority carrier provided from source the transistor and the carriers extracted by drain of the transistor are electrons instead of holes. On the contrary, the term “p-type field effect transistor (p-type FET)” used here means the majority carrier are holes instead of electrons. An “enhancement-mode” transistor is also called a normally-off transistor and is in contrast to a “depletion-mode” transistor which has conducting current flowing between its source and drain at zero gate voltage. The inventors of the present invention discovered that an ultra-thin metal oxide channel layer can be used for an n-type FET to achieve unexpected results. The term “ultra-thin metal oxide channel layer” under the context of the present invention means a metal oxide channel layer having a thickness less than a threshold value. The metal oxide under the context of the present invention comprises especially metal oxides selected from stannic oxide (SnO₂), Indium tin oxide (ITO), Zinc oxide (ZnO), stannous oxide (SnO), Indium(III) oxide (In₂O₃), etc. The threshold value for SnO₂ for example is less than 10 nm. However, for other metal oxide materials, such threshold value for thickness is so defined that with a thickness less than such threshold value the metal oxide channel layer would exhibit pinch-off behavior in transfer characteristics and has a mobility trend without saturation region. With such a threshold thickness, the metal oxide channel layer has an upper threshold conductivity. When the thickness of the metal oxide channel layer reduces (i.e. lower than the threshold thickness), the conductivity of the metal oxide channel layer reduces while the metal oxide channel layer still exhibits pinch off behavior. However, the conductivity may not be too low (i.e. less than a lower threshold conductivity) because low conductivity would lead to detrimental high channel resistance. Thus, the conductivity of the metal oxide channel layer for an n-type FET is bounded by the upper threshold conductivity and the lower threshold conductivity._Preferably, for the metal oxide channel layer to have proper pinch off behavior and to be semi-conductive instead of insulating, the upper threshold conductivity is about 10⁵ S/m and the lower threshold conductivity is about 1 S/m; i.e., the conductivity of the metal oxide channel layer is between 10⁵ S/m and 1 S/m.

Now referring to FIG. 2, the n-type FET 200 of the present invention comprises a substrate 1, an optional insulting layer 3 on the substrate 1, a metal oxide channel layer 4 on the optional insulting layer 3, a gate stack on the metal oxide channel layer 4, and spacers 28 at two sides of the gate electrode 29. The gate stack comprises an optional interfacial layer 26 on the metal oxide channel layer 4, a gate dielectric layer 27 such as a high-k dielectric layer interposed between a metal gate electrode 29 and the metal oxide channel layer 4, and the gate electrode 29. The metal oxide channel layer 4 provides a controllable electrical pathway under the metal gate electrode 29 between a source and a drain (not shown in FIG. 2) within the metal oxide channel layer 4. For example, the substrate 1 may be a glass substrate, a single crystalline Si substrate, a silicon-on-insulator (SOI) substrate, a material substrate with a strained layer thereon, a material substrate with an insulating layer thereon, etc. In a case where the substrate 1 comprises an insulating upper surface such as a silicon-on-insulator (SOI) substrate, the optional insulating layer 3 may be omitted. For example, the metal oxide channel layer 4 may use one or more metal oxides selected from SnO₂, ITO, ZnO, SnO, In₂O₃, etc. For example, the high-k dielectric material used for the gate dielectric layer 27 may be silicon nitride (Si₃N₄), oxynitride (SiON), hafnium silicate (HfSiO₄), hafnium dioxide (HfO₂), zirconium silicate (ZrSiO₄), zirconium dioxide (ZrO₂), hafnium silicon oxide (HfSiO), hafnium silicon oxynitride (HfSiON), hafnium tantalum oxide (HfTaO), hafnium titanium oxide (HfTiO), hafnium zirconium oxide (HfZrO), hafnium lanthanum oxide (HfLaO), hafnium lutetium oxide (HfLuO), aluminum oxide (Al₂O₃), a combination thereof, or any dielectric materials having dielectric constant higher than that of SiO₂. In a case where a high-k dielectric material such as hafnium dioxide is used for the gate dielectric layer 27, the optional interfacial layer 26 is needed due to potential incompatibility between the high-k dielectric material and the metal oxide channel layer 4. If a commonly used gate dielectric material such as silicon dioxide is used for the gate dielectric layer 27, the optional interfacial layer 26 may be omitted. For example, the optional interfacial layer 26 may use silicon dioxide. The thickness of the optional interfacial layer 26 is not limited to a specific range of values but it is preferably to use a thickness as thin as possible such as less than 1 nm especially 0.5 nm to keep the total gate dielectric capacitance high. The thickness of the gate dielectric layer 27 is not limited to a specific range of values but with considerations of transistor leakage current and transistor performance (impacted by gate dielectric capacitance) in mind it is preferably to use a thickness of a few nanometer (nm) such as less than 5 nm especially 3 nm. It is noted that the thinner the gate dielectric layer 27 is the higher leakage current occurs due to tunneling effect. Although in FIG. 2 the metal gate electrode 29 is shown as a bulk single layer, it actually represents multiple layers including an optional bottom barrier layer, an optional etching stop layer used to protect material films in n-type FET region while removing a portion of a layer used for p-type FET, an n-type (or mid-gate) work-function tuning layer, an optional top barrier layer, an optional wetting layer, a bulk low-resistivity conductive layer, etc. It is worth mentioning that the materials and thicknesses of these listed layers would affect the work function of the n-type FET 200 so the combination of their materials and thicknesses must be fine tuned. Usually, all the layers except the bulk low-resistivity conductive layer have thin thickness ranging from few angstroms to tens of few angstroms. For example, the optional bottom and top barrier layers and the optional etching stop layer may use the same or different metal nitrides such as titanium nitride (TiN) or tantalum nitride (TaN). For example, the n-type work-function tuning layer may use titanium aluminum (TiAl) with or without impurities such as silicon atoms, titanium aluminum nitride (TiAlN) with or without impurities, a combination thereof, or any metallic material or metal alloying having a work-function between 3.9 eV and 4.3 eV. For example, the mid-gate work function tuning layer may use titanium nitride (TiN) of different titanium to nitrogen ratios. The bulk low-resistivity conductive layer may use materials commonly adopted for back-end-of-line (BEOL) interconnect such as tungsten (W), aluminum (Al), copper (Cu), an alloy thereof, or a combination thereof. Sometimes an optional dielectric capping layer for tuning work-function can be formed between the gate dielectric layer 27 and the metal gate electrode 29, and an optional metal oxide/nitride hard mask layer for facilitating later-formed metal contacts can be formed on the metal gate electrode 29. For example, the optional dielectric capping layer may use lanthanum oxide (LaOx) for n-type FET and the optional metal oxide/nitride hard mask layer may use titanium aluminum oxide (TiAlO). Although each of the spacers 28 is shown as a single sail-shaped layer, each of the spacers 28 may comprise two or more spacers of different shapes such as a linear shape and a sail-shape. Furthermore, the spacers 28 at two sides of the gate stack of the n-type FET may look like two individual and separate spacers, but in a top view they are parts of a ring-shaped spacer surrounding the gate stack. For example, the spacers 28 may use dielectric materials such as silicon dioxide (SiO₂), silicon nitride (Si₃N₄), oxynitride (SiON), silicon carbide (SiC), and silicon carbon nitride (SiCN).

The present invention mainly focuses on the metal oxide SnO₂ channel layer 4 and its electrical characteristics, but the results and conclusions obtained for SnO₂ may be equally applied to other metal oxides listed above. The inventors of the present invention conducted some experiments on a test FET having various metal oxide SnO₂ channel layer thicknesses and found the thickness of the metal oxide SnO₂ channel layer is critical for proper pinch-off behavior in transfer characteristics. When the thickness of the metal oxide SnO₂ channel layer is larger than a threshold value, the test field effect transistor failed to show proper pinch-off behavior. When the thickness of the metal oxide SnO₂ channel layer is smaller than a threshold value, the test field effect transistor exhibited proper pinch-off behavior. Not to be bound by any principles or theories, inventors of the present invention assume the test field effect transistor having a metal oxide SnO₂ channel layer thickness larger than the threshold value failed to show proper pinch off because of high conductivity of such channel layer. To support such assumption, inventors of the present invention measured the conductivities of the metal oxide SnO₂ channel layers having different thicknesses and obtained conductivities of 3.6×10⁵, 1.7×10⁵, and 9.3×10⁴ S/m respectively. Inventors' experiments led them to a conclusion that the thickness of the metal oxide channel layer 4 is preferably less than a threshold value (10 nm for SnO₂ under the conditions of the experiments). A similar conclusion is deduced: with such a threshold thickness, the metal oxide channel layer has an upper threshold conductivity; when the thickness of the metal oxide channel layer reduces (i.e. lower than the threshold thickness), the conductivity of the metal oxide channel layer reduces while the metal oxide channel layer still exhibits pinch off behavior; however, the conductivity may not be too low (i.e. less than a lower threshold conductivity) because low conductivity would lead to detrimental high channel resistance. Thus, the conductivity of the metal oxide channel layer for an n-type FET is bounded by the upper threshold conductivity and the lower threshold conductivity. Preferably, for the metal oxide channel layer to have proper pinch off behavior and to be semi-conductive instead of insulating, the upper threshold conductivity is about 10⁵ S/m and the lower threshold conductivity is about 1 S/m; i.e., the conductivity of the metal oxide channel layer is between 10⁵ S/m and 1 S/m. If other metal oxides are used as the metal oxide channel layer 4, the preferable thickness range and conductivity range thereof may vary according to their physical and/or chemical properties. Furthermore, the threshold value for an advanced HKMG (high-k gate dielectric and metal gate) field effect transistor using a SnO₂ channel layer (or fin-type field effect transistor using a SnO₂ channel layer) may not be 10 nm due to the differences such as device dimension, device structure, materials used, etc. between the HKMG field effect transistor (or fin-type FET) and the test field effect transistor. Another critical behavior found through the experiments conducted on the test field effect transistor having various metal oxide SnO₂ channel layer thicknesses is that the effective mobilities (μ_{FE}) of electrons at the channel layers with thicknesses larger than the threshold value increase with the increase of gate voltage (V_{GS}) but would saturate after certain points of gate voltages (V_{GS}) while the effective mobilities (μ_{FE}) of electrons at the channel layers with thicknesses smaller than the threshold value increase with the increase of gate voltage (V_{GS}) without saturation observed. For the test field effect transistor having metal oxide SnO₂ channel layer thickness of 4.5 nm, the effective mobility (μ_{FE}) of electrons at the metal oxide SnO₂ channel layer even reaches to an unreported high level of 147 cm²/Vs. The inventors of the present invention believe such high level of effective mobility is achieved due to fully depletion of the ultra-thin metal oxide SnO₂ channel layer. The fully depleted ultra-thin metal oxide SnO₂ channel layer allows the majority carriers (electrons) to flow near the interface between the fully depleted ultra-thin metal oxide SnO₂ channel layer and the dielectric layer (the optional interfacial layer 26 and the gate dielectric layer 27) adjacent to it. Without being scattered in the bulk metal oxide SnO₂ channel layer, the electrons even reach an unreported high level of mobility 147 cm²/Vs. Furthermore, the test field effect transistor having metal oxide SnO₂ channel layer thickness of 4.5 nm exhibits good transistor characteristics at a low V_{DS} of 0.1V. It is found that the test field effect transistor having metal oxide SnO₂ channel layer thickness of 4.5 nm exhibits a large on-current over off-current (I_{ON}/I_{OFF})>107, a low threshold voltage V_{T} of 0.27 V, and a small sub-threshold swing (SS) of 110 mV/dec indicating fast turn-on and aggressive driving capability.

Now still referring to FIG. 2, the p-type FET 100 of the present invention comprises the substrate 1, a germanium (Ge)-containing channel layer 2 on the substrate 1, a gate stack on the germanium-containing channel layer 2, source 31 and drain 32 within the germanium-containing channel layer 2, and spacers 18 at two sides of the gate stack. The gate stack comprises an optional interfacial layer 16 on the germanium-containing channel layer 2, a gate dielectric layer 17 such as a high-k dielectric layer interposed between a metal gate electrode 19 and the germanium-containing channel layer 2, and the gate electrode 19. The germanium-containing channel layer 2 provides a controllable electrical pathway under the metal gate electrode 19 between the source 31 and the drain 32 within the germanium-containing channel layer 2. The substrate 1 is the same as the substrate 1 of the n-type FET 200 so its descriptions are omitted. For example, the germanium-containing channel layer 2 may use a silicon-germanium (SiGe) or pure germanium (Ge) layer formed by epitaxial growth, wafer bonding, smart-cut process, chemical vapor deposition process with germanium atoms introduced by diffusion or implant process, evaporation deposition process, or a silicon-germanium or pure germanium layer of a germanium on insulator (GOI) substrate. If a silicon-germanium layer is used, silicon to germanium atomic ratio may vary according to device performance and/or process window. Alternatively, the germanium-containing channel layer 2 may use a binary or ternary germanium compound with germanium atomic ratio ranging from 20% to 99%. Moreover, the germanium-containing channel layer 2 may be a strained layer such as a compressive layer to further increase carrier mobility. The gate dielectric layer 17 is the same as the gate dielectric layer 27 of the n-type FET 200 so its descriptions are omitted. In a case where a high-k dielectric material such as hafnium dioxide is used for the gate dielectric layer 17, the optional interfacial layer 16 is needed due to incompatibility between the high-k dielectric material and germanium-containing channel layer 2. If a commonly used gate dielectric material such as silicon dioxide is used for the gate dielectric layer 17, the optional interfacial layer 16 may be omitted. For example, the optional interfacial layer 16 may use silicon dioxide or germanium dioxide formed by oxidizing the germanium-containing channel layer 2. The thickness of the optional interfacial layer 16 is not limited to a specific range of values but it is preferably to use a thickness as thin as possible such as less than 1 nm especially 0.5 nm to keep the total gate dielectric capacitance high. Although in FIG. 2 the metal gate electrode 19 is shown as a bulk single layer, it actually represents multiple layers including an optional bottom barrier layer, an optional etching stop layer used to protect material films in n-type FET region while removing a portion of a layer used for p-type FET, a p-type (or mid-gate) work-function tuning layer, an optional top barrier layer, an optional wetting layer, a bulk low-resistivity conductive layer, etc. Except the p-type work-function tuning layer of the metal gate electrode 19 is different from the n-type work-function tuning layer of the metal gate electrode 29, the rest of the layers of the metal gate electrode 19 are almost the same as the rest of the layers of the metal gate electrode 29 and their descriptions are omitted. For example, the p-type work-function tuning layer may use titanium nitride (TiN), tantalum nitride (TaN), molybdenum nitride (MoN), or any metallic material or metal alloying having a work-function between 4.8 eV and 5.2 eV. Sometimes an optional dielectric capping layer for tuning work-function can be formed between the gate dielectric layer 17 and the metal gate electrode 19, and an optional metal oxide/nitride hard mask layer for facilitating later-formed metal contacts can be formed on the metal gate electrode 19. For example, the optional dielectric capping layer may use aluminum oxide (Al₂O₃) for p-type FET and the optional metal oxide/nitride hard mask layer may use titanium aluminum oxide (TiAlO).

Now referring to FIGS. 1-2, in order to fabricate the complementary transistor pair comprising the p-type FET 100 and the n-type FET 200, a method for manufacturing a complementary transistor pair is disclosed. First, a substrate 1 comprising a predetermined region 10 for forming the p-type FET 100 and a predetermined region 20 for forming the n-type FET 200 with the germanium-containing channel layer 2 in the predetermined region 10 on the substrate 1 and the optional insulting layer 3 and the metal oxide channel layer 4 in the predetermined region 20 on the substrate 1 is provided as shown in FIG. 1. It is noted that as mentioned earlier the germanium-containing channel layer 2 may be a part of the substrate 1 if a germanium on insulator substrate is used and in such a case the optional insulating layer 3 may be also a part of the substrate 1 with the germanium layer of the germanium on insulator substrate removed. The processes to provide different channel layers in the predetermined regions 10 and 20 may involve blanket growth and partially removal of a film or selective growth of a film. As mentioned earlier, the germanium-containing channel layer 2 may be formed by epitaxial growth process, wafer bonding process, smart-cut process, chemical vapor deposition (CVD) process with germanium atoms introduced by diffusion or implant process, evaporation deposition process, or provided by a germanium on insulator (GOI) substrate. The metal oxide channel layer 4 is preferably formed by evaporation deposition process and annealed at a low temperature less than 550° C. in an environment containing oxygen gas (O₂) by rapid thermal anneal process. The metal oxide channel layer 4 as deposited is at amorphous state or nano-crystalline state, and remains amorphous state or nano-crystalline state after being annealed. The metal oxide channel layer 4 may also be formed through CVD process, epitaxial growing process, atomic layer deposition (ALD) process, etc. and the annealing process may be omitted if other material(s) is used or such annealing process is deemed unnecessary. The germanium-containing channel layer may be formed before or after formation of the metal oxide channel layer 4. Then, a shallow trench isolation structure 5 is formed between the predetermined regions 10 and 20 to electrically isolate the p-type FET 100 and the n-type FET 200 to be formed. However, the present invention is not limited to the sequence of forming the germanium-containing channel layer 2, optional insulating layer 3, the metal oxide channel layer 4 and the shallow trench isolation structure 5 addressed here. The shallow trench isolation structure 5 may be formed before formations of the germanium-containing channel layer 2, optional insulating layer 3 and the metal oxide channel layer 4.

Then, the gate stack comprising the optional interfacial layer 16, the gate dielectric layer 17, and the gate electrode 19 for the p-type FET 100, and the gate stack comprising the optional interfacial layer 26, the gate dielectric layer 27, and the gate electrode 29 for the n-type FET 200 are formed in the predetermined region 10 and the predetermined region 20 respectively as shown in FIG. 2. The optional interfacial layer 16 and the optional interfacial layer 26 may be formed from the same material such as silicon dioxide (SiO₂) and by the same process such as CVD or ALD process simultaneously, or they may be formed from different materials such as germanium oxide (GeO₂) and silicon dioxide (SiO₂) and by different processes such as CVD process and thermal oxidation process. The gate dielectric layer 17 and the gate dielectric layer 27 may be formed from the same material and by the same process such as ALD process simultaneously. As for the gate electrode 19 and the gate electrode 29, they may use the same materials for the optional bottom barrier layer, the optional etching stop layer, the optional top barrier layer, the optional wetting layer, and the bulk low-resistivity conductive layer but use different materials for the work-function tuning layer due to different work-functions required. Furthermore, the gate electrode 19 may have less or more layers than the gate electrode 29. All the layers in the gate electrode 19 and gate electrode 29 may be formed by CVD process, physical vapor deposition (PVD) process, ALD process, evaporation deposition process, reactive sputtering process, annealing process in an environment containing specific gas (gases), etc. If a layer is only required for one of the n-type FET 200 and the p-type FET, a selective removing process is performed to remove it partially. The patterning of the gate stacks usually involve lithography process and one or more etching processes to pattern film stacks comprising the listed layers.

After forming the gate stacks, the spacers 18 and the spacers 28 are formed by depositing one or more dielectric layers blanketly on the substrate and performing one or more etching processes to etch horizontal portions of the dielectric layers and leave vertical portions of the dielectric layers on sidewalls of the gate stacks. Before, after or during (if each spacer comprise multiple spacers) forming the spacers 18 and the spacers 28, one or more ion implant processes are performed to form lightly doped drains (LDD, not shown in FIG. 2), and the source 31 and the drain 32. However, these kind of implant processes are optional to the n-type FET of the present invention due to fair conductivity of the metal oxide channel layer 4. Furthermore, a channel implant process may be optionally performed to the channel regions of the germanium containing channel layer 2 and the metal oxide channel layer 4 to adjust electrical properties such as threshold voltage of the p-type FET 100 and the n-type FET 200. If the germanium containing channel layer 2 and the metal oxide channel layer 4 are incapable of forming ohmic contacts with the later-formed contacts, an extra layer such as a silicide layer may be formed between the germanium containing channel layer 2 and the contacts and between the metal oxide channel layer 4 and the contacts. Now the p-type FET 100 and the n-type FET 200 are completed. Afterward, a contact etching stop layer (CESL) such as a silicon nitride layer (not shown) and an interlayer dielectric layer (ILD) 35 may be formed on the p-type FET 100 and the n-type FET 200 to protect the completed the p-type FET 100 and the n-type FET 200. Although the interlayer dielectric layer (ILD) 35 is shown as a single bulk layer, it may comprise multiple dielectric layers. Electrical contacts (not shown) may be formed penetrating the contact etching stop layer (CESL) and the interlayer dielectric layer 35 and contacting the gate stacks, the metal oxide channel layer 4, the source 31, and the drain 32 to apply voltages or pick up signals.

The method for manufacturing a complementary transistor pair shown in FIGS. 1-2 is a gate-first high-k first method for manufacturing high-k dielectric metal-gate transistors. The method is called “gate-first high-k first” process because the metal gate and high-k gate dielectric layer are formed before formations of source and drain. In the gate-first high-k first method, the work-function tuning layers and high-k gate dielectric layers have to go through high activation temperature such as a temperature higher than 1000° C. of the source and the drain, so the threshold voltages and other electrical properties of the transistors may be negatively affected. Nevertheless the gate-first high-k first method is similar to the traditional CMOS manufacturing method, gate-last high-k first or gate-last high-k last methods are developed to overcome the drawbacks of the gate-first high-k first method.

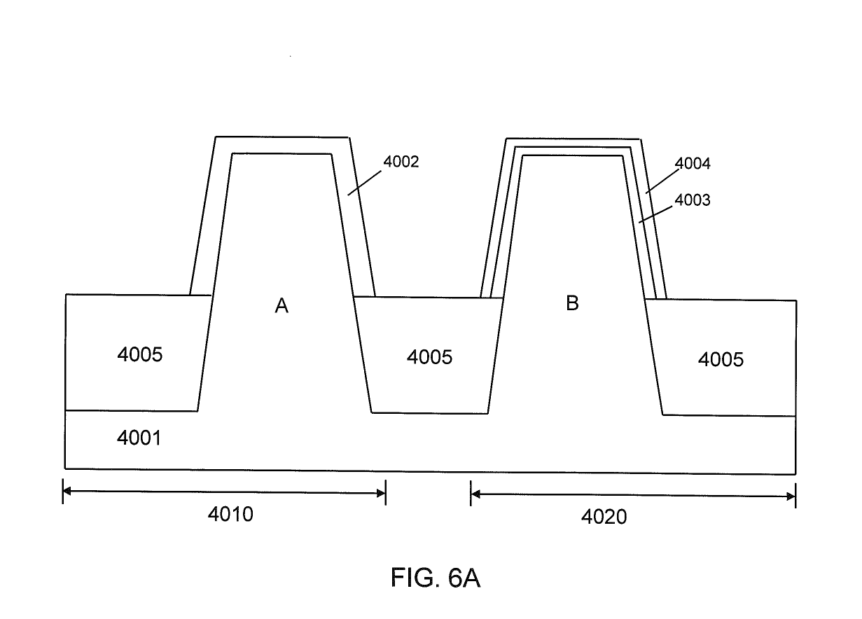

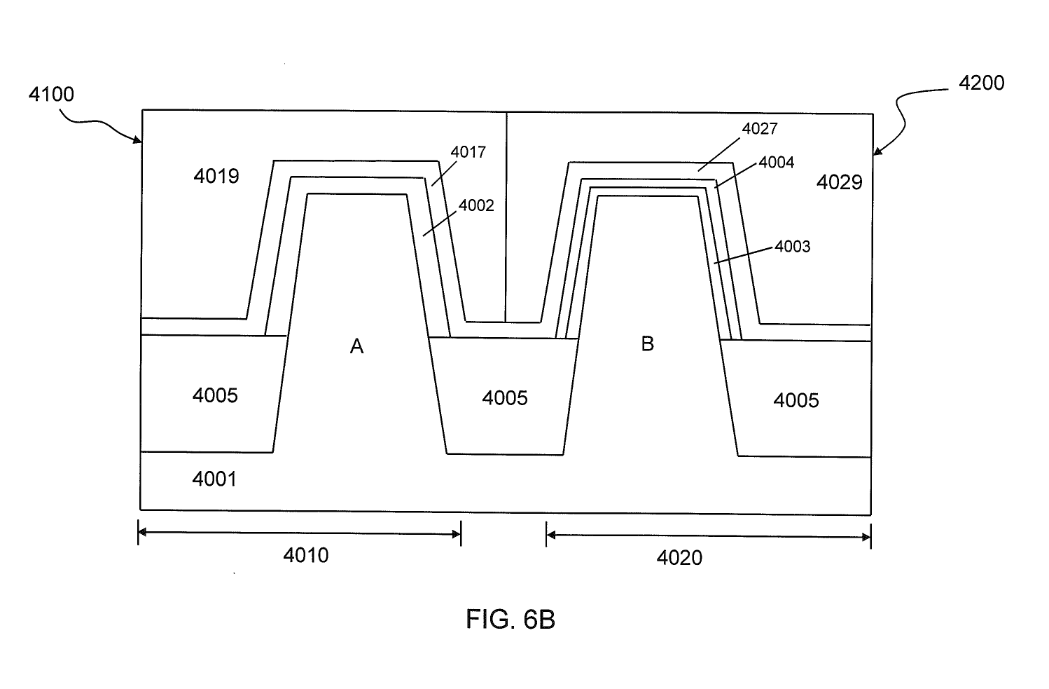

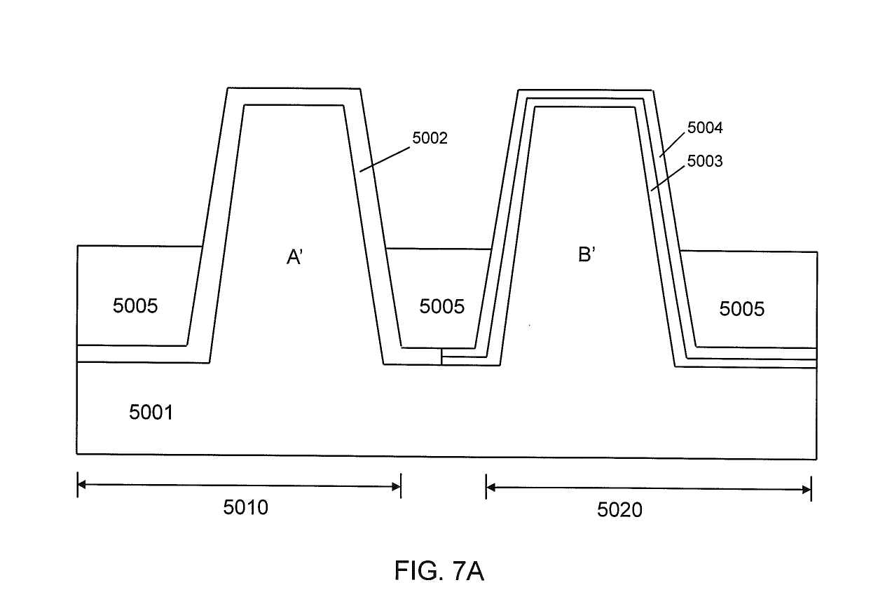

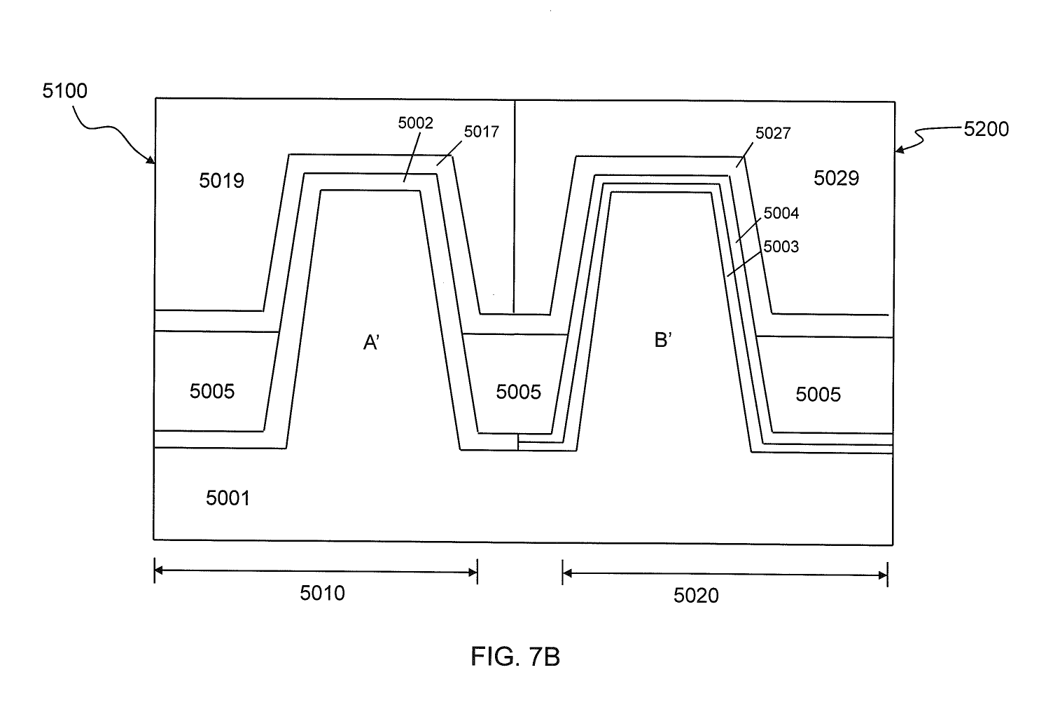

In the following embodiments, similar numbers are used for similar elements. For example, numbers 10, 1010, 2010, 3010, 4010 all have 10 as their last two digits and they all represent a predetermined region for forming a p-type FET. For example, numbers 20, 1020, 2020, 3020, 4020 all have 20 as their last two digits and they all represent a predetermined region for forming an n-type FET. Similarly, the last digit 1, 2, 3, 4, and 5 represent a substrate, a germanium containing channel layer, an optional insulating layer, a metal oxide channel layer, and a trench isolation structure respectively. The last two digits 16, 17, 18, 19, 31, and 32 represent an optional interfacial layer, a gate dielectric layer, a spacer, a metal gate electrode, a source, and a drain of a p-type field effective transistor respectively. The last two digits 26, 27, 28, and 29 represent an optional interfacial layer, a gate dielectric layer, a spacer, and a metal gate electrode of an n-type field effective transistor respectively. Although in the following embodiments the sequence of forming these elements may vary, the materials and processes suitable for forming these elements are similar to the embodiment described with reference to FIGS. 1-2 and are omitted to save meaningless repetitions. Especially, each of the metal oxide channel layers 4 (FIGS. 1-2, 3A-3B, 4A-4D, and 5), 4004 (FIGS. 6A-6B), 5004 (FIG. 7A-7B) has a ultra-thin thickness less than a threshold value rendering pinch-off behavior in transfer characteristics and mobility trend without saturation. With such ultra-thin thickness less than the threshold value, the conductivities of these the metal oxide channel layers 4 (FIGS. 1-2, 3A-3B, 4A-4D, and 5), 4004 (FIGS. 6A-6B), 5004 (FIG. 7A-7B) are less than an upper threshold value to render proper pinch off behaviors and more than a lower threshold value to become semi-conductive instead of insulating. For a planar (two dimensional) high-k metal-gate n-type FET such as the n-type FET shown in FIGS. 2, 3B, 4D and 5, such an ultra-thin metal oxide channel layer would make them compatible with the next generation vertical (three dimensional) n-type fin-type FET in terms of their electrical performances due to fully depletion of such an ultra-thin metal oxide channel during transistor operation.

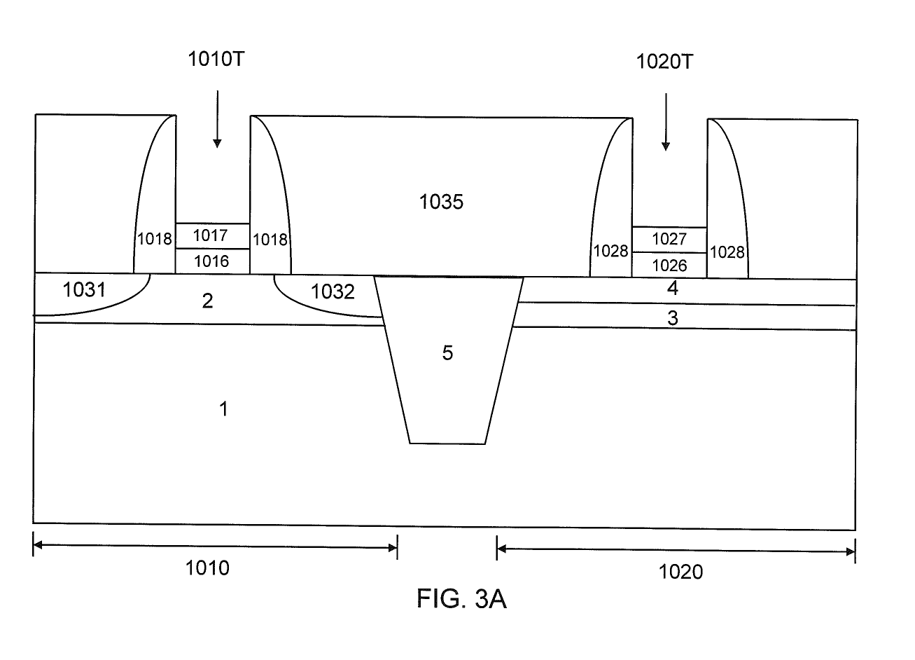

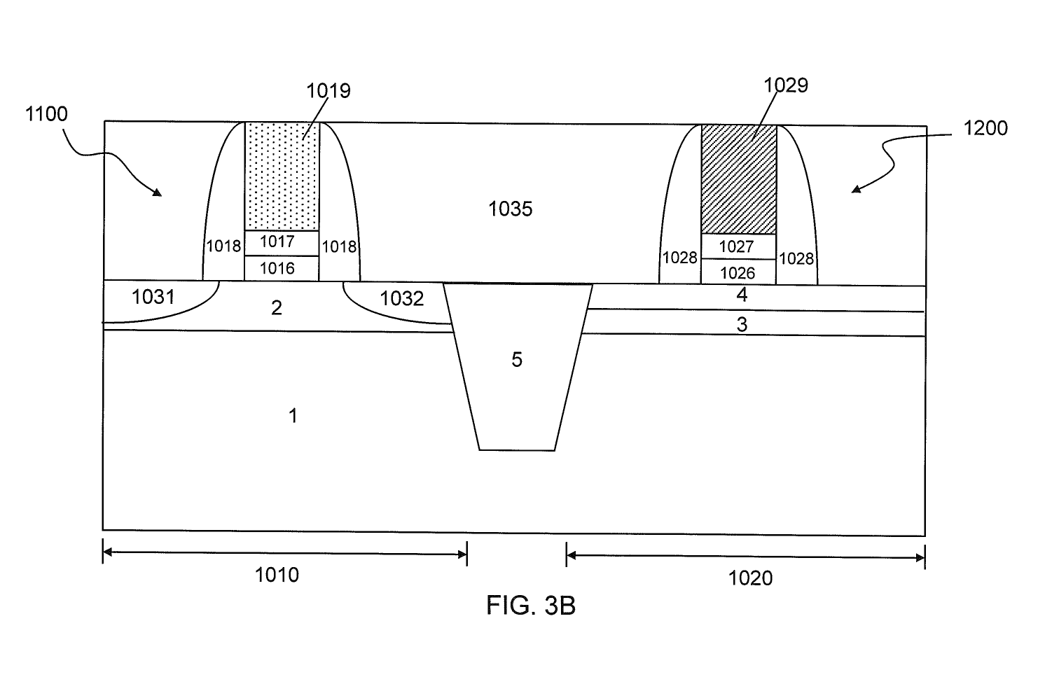

Now referring to FIGS. 1 and 3A-3B, FIGS. 1, 3A and 3B are schematic cross-sectional views illustrating an exemplary complementary transistor pair comprising a p-type FET 1100 and an n-type FET 1200 according to another embodiment of the present invention and method for manufacturing such transistor pair. The method for manufacturing the complementary transistor pair shown in FIGS. 1 and 3A-3B is a gate-last high-k first process for manufacturing high-k dielectric metal-gate transistors. First, a substrate 1 comprising a predetermined region 1010 for forming the p-type FET 1100 and a predetermined region 1020 for forming the n-type FET 1200 with the germanium-containing channel layer 2 in the predetermined region 1010 on the substrate 1 and the optional insulting layer 3 and the metal oxide channel layer 4 in the predetermined region 1020 on the substrate 1 is provided similar to the cross-sectional view shown in FIG. 1. The predetermined regions 1010 and 1020 are the same as the predetermined regions 10 and 20 of FIG. 1. The germanium-containing channel layer 2, the optional insulting layer 3, and the metal oxide channel layer 4 are the same as the ones shown in FIG. 1 and their descriptions are omitted. Before or after formations of the germanium-containing channel layer 2, the optional insulting layer 3, and the metal oxide channel layer 4, a shallow trench isolation structure 5 is formed between the predetermined regions 1010 and 1020 to electrically isolate the p-type FET 1100 and the n-type FET 1200 to be formed. Then, a dummy gate stack (not fully shown) comprising an optional interfacial layer 1016, a gate dielectric layer 1017, and a dummy gate electrode (not shown) for the p-type FET 1100, and a dummy gate stack (not fully shown) comprising an optional interfacial layer 1026, a gate dielectric layer 1027, and a dummy gate electrode (not shown) for the n-type FET 1200 are formed in the predetermined region 1010 and the predetermined region 1020 respectively as shown in FIG. 3A. The dummy gate electrode for the p-type FET 1100 and the dummy gate electrode for the n-type FET 1200 may use any material that is easy to be removed and has etching selectivity to the material of the underlying gate dielectric layers, the material(s) of the later-formed spacers, the material(s) of the later-formed contact etching stop layer (CESL) and interlayer dielectric layer ILD. It is noted that an optional dielectric hard mask layer such as a silicon nitride layer may be formed on each of the dummy gate electrodes in the dummy gate stacks to facilitate controlling of a later-performed planarization process. A pure silicon material such as single crystalline silicon, amorphous silicon, or polysilicon may be used to form both dummy gate electrodes for the p-type FET 1100 and the n-type FET 1200. The patterning process of the dummy gate stacks are similar to the patterning process of the gate stacks of FIG. 2. Then, the spacers 1018 and the spacers 1028 are formed beside the dummy gate stacks. Before, after or during (if each spacer comprise multiple spacers) forming the spacers 1018 and the spacers 1028, one or more ion implant processes are performed to form lightly doped drains (LDD, not shown in FIG. 3A), and the source 1031 and the drain 1032. As mentioned earlier with reference to FIGS. 1-2, a channel implant process and an extra layer such as a silicide layer may be optionally performed and formed. Afterward, a contact etching stop layer (CESL) such as a silicon nitride layer (not shown) and one or more interlayer dielectric materials (not shown) are formed on the substrate 1 covering the dummy gate stack (not fully shown), the spacers 1018, and the source 1031 and the drain 1032 for the p-type FET 1100, and the dummy gate stack (not fully shown), the spacers 1028, and the metal oxide channel layer 4 for the n-type FET 1200. Next, a planarization process such as a chemical mechanical polishing process is performed using the optional dielectric hard mask layers (if exist) of the dummy gate stacks or the dummy gate electrodes of the dummy gate stacks as polishing stop layer to form the planarized interlayer dielectric layer 1035 and to achieve a global planar surface. At this stage, the upper surfaces of the dummy gate stacks (upper surfaces of the optional dielectric hard mask layers if used, or upper surfaces of the dummy gate electrodes) are coplanar with the upper surface or the planarized interlayer dielectric layer 1035 (not shown). Then, one or more etching processes are performed to remove the dielectric hard mask layer (if used) and the dummy gate electrodes for the p-type FET 1100 and for the n-type FET 1200 so as to form a gate trench 1010T for the p-type FET 1100 and a gate trench 1020T for the n-type FET 1200 simultaneously as shown in FIG. 3A.

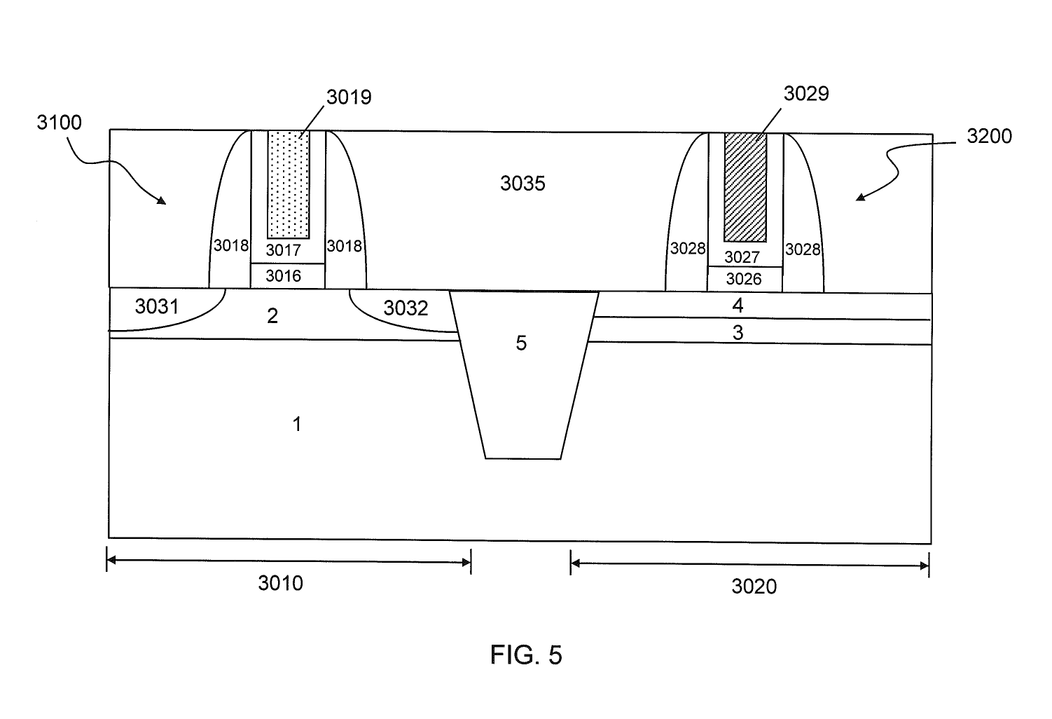

Next, an optional bottom barrier layer (not shown), an optional etching stop layer (not shown), and a p-type work-function tuning layer (not shown) are conformally and blanketly formed on the substrate 1 and in the gate trench 1010T and the gate trench 1020T lining sidewalls and bottoms of the gate trench 1010T and the gate trench 1020T. Then, optionally, a patterned mask layer such as a patterned photoresist layer or a patterned dielectric layer is formed to protect the predetermined region 1010 and expose the predetermined region 1020, a dry etching process is performed to remove the p-type work-function tuning layer in the exposed predetermined region 1020, and a removing process (ashing process for the patterned photoresist layer or etching process for the patterned dielectric layer) is performed to remove the patterned mask layer. Afterward, an n-type work-function tuning layer (not shown), an optional top barrier layer (not shown), and an optional wetting layer (not shown) are conformally and blanketly formed on the substrate 1 and in the gate trench 1010T and the gate trench 1020T lining sidewalls and bottoms of the gate trench 1010T and the gate trench 1020T. Then, a bulk low-resistivity conductive layer (not shown) is formed on the substrate 1 filling in the rest spaces of the gate trench 1010T and the gate trench 1020T. It is noted that the p-type work-function tuning layer does not have to be removed from the predetermined region 1020 if it is thin enough that it may not affect the n-type work-function of the n-type FET 1200 or if there is other measures taken to compensate the influence on the n-type work-function. It is also noted that any one of these layers may be removed from one of the predetermined regions 1010 and 1020 in a similar way by which the p-type work-function tuning layer is removed from the predetermined region 1020. Furthermore, due to limited spaces of the trenches 1010T and 1020T, some of these layers may be formed by treatments such as oxidation, nitridation, or ion implant process instead of deposition process and one or more of these layers may be trimmed or thinned to give more space for other layers. After the trenches 1010T and 1020T are filled with the bulk low-resistivity conductive layer (not shown), one or more planarization processes such as one or more chemical mechanical polishing processes are performed to remove parts of these layers outside the trenches 1010T and 1020T to achieve a global surface and to form the gate electrode 1019 and the gate electrode 1029. Now the p-type FET 1100 and the n-type FET 1200 are completed. Afterward, electrical contacts (not shown) may be formed penetrating the contact etching stop layer (CESL) and the planarized interlayer dielectric layer 1035 and contacting the gate electrodes, the metal oxide channel layer 4, the source 1031, and the drain 1032 to apply voltages or pick up signals. Due to the nature of this gate-last high-k first process, all the layers conformally formed lining the sidewalls and bottoms of the trenches 1010T and 1020T would be U-shaped (not shown) in a cross-sectional view as the U-shaped gate dielectric layers 3017 and 3027 of FIG. 5.

The method for manufacturing a complementary transistor pair shown in FIGS. 1 and 3A-3B is a gate-last high-k first method for manufacturing high-k dielectric metal-gate transistors. The method is called “gate-last high-k first” method because the metal gate is formed after formations of source and drain while the high-k gate dielectric layer is formed before formations of source and drain. Compared to the gate-first high-k first method shown in FIGS. 1-2, the gate-last high-k first method shown in FIGS. 1 and 3A-3B is relatively complex and different from the traditional CMOS manufacturing method.

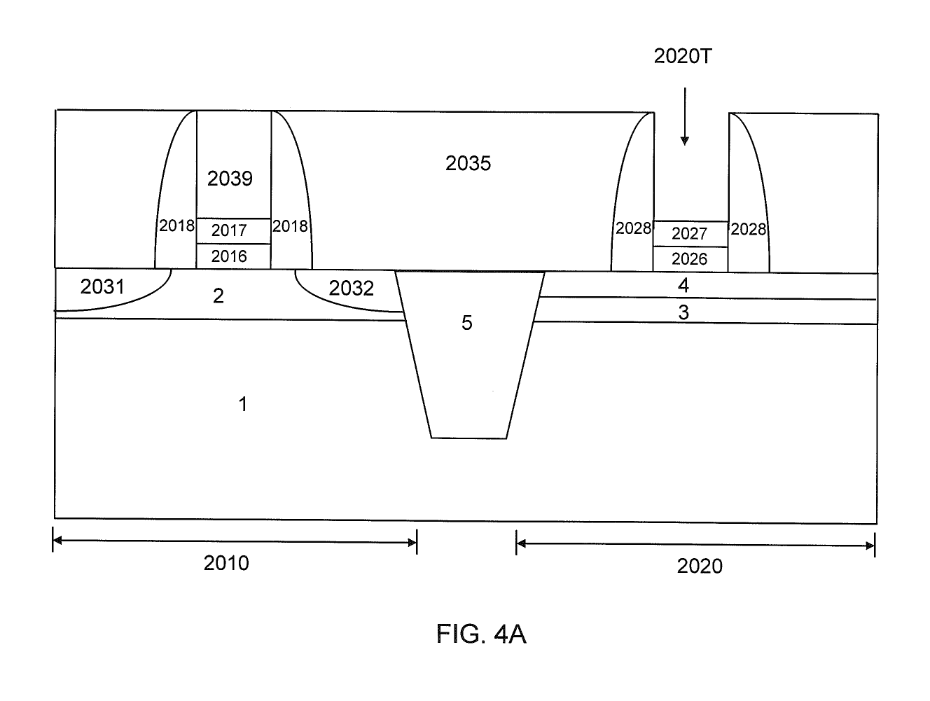

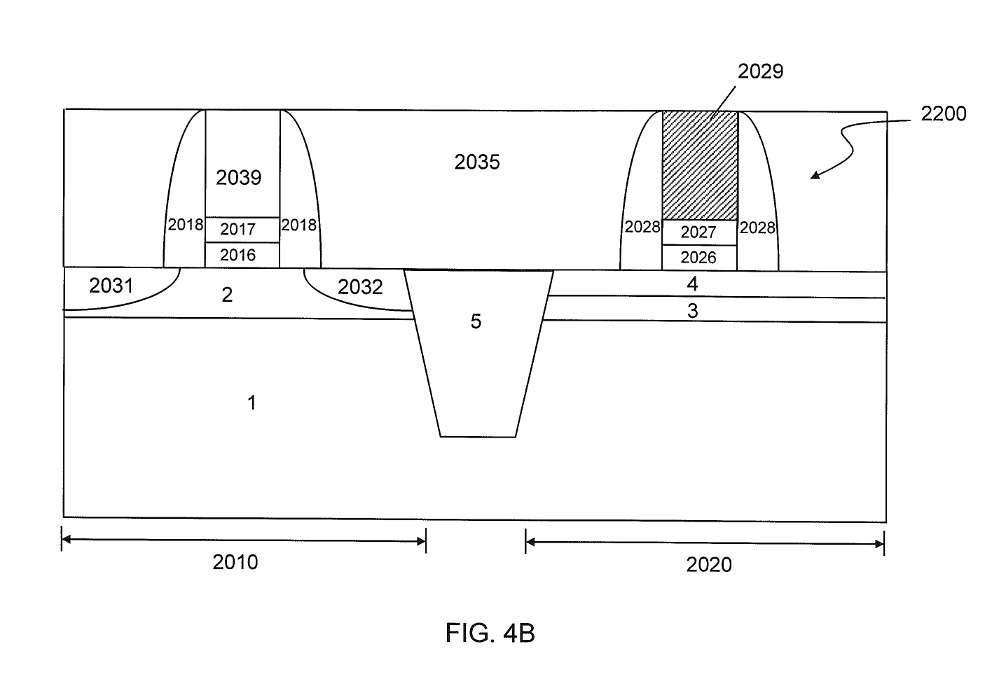

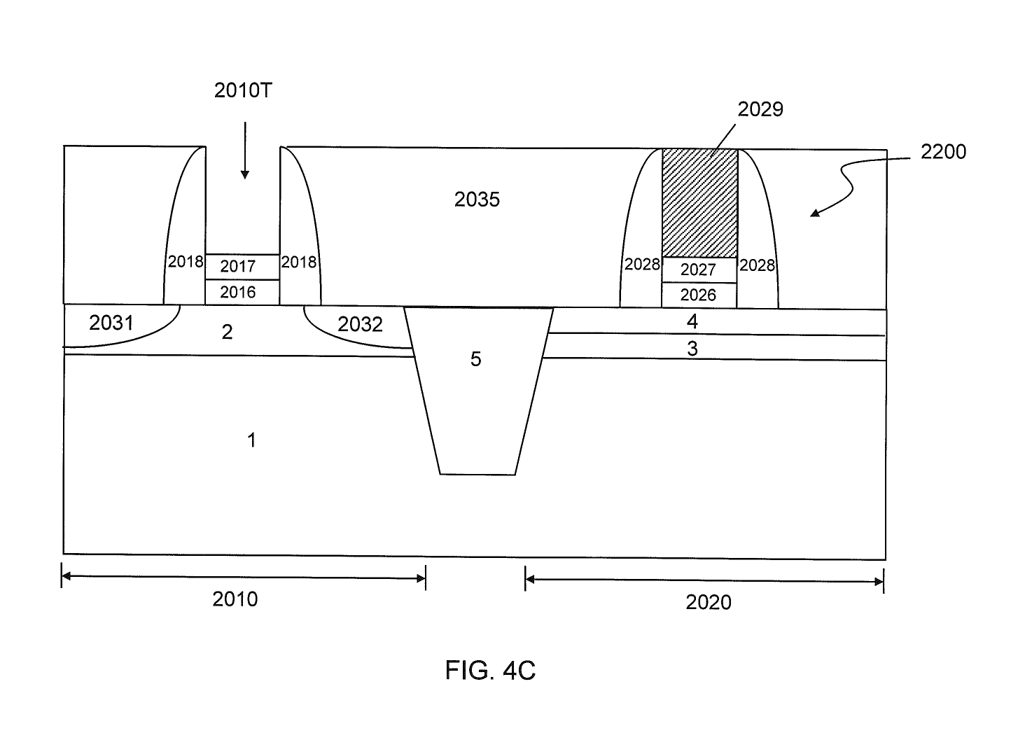

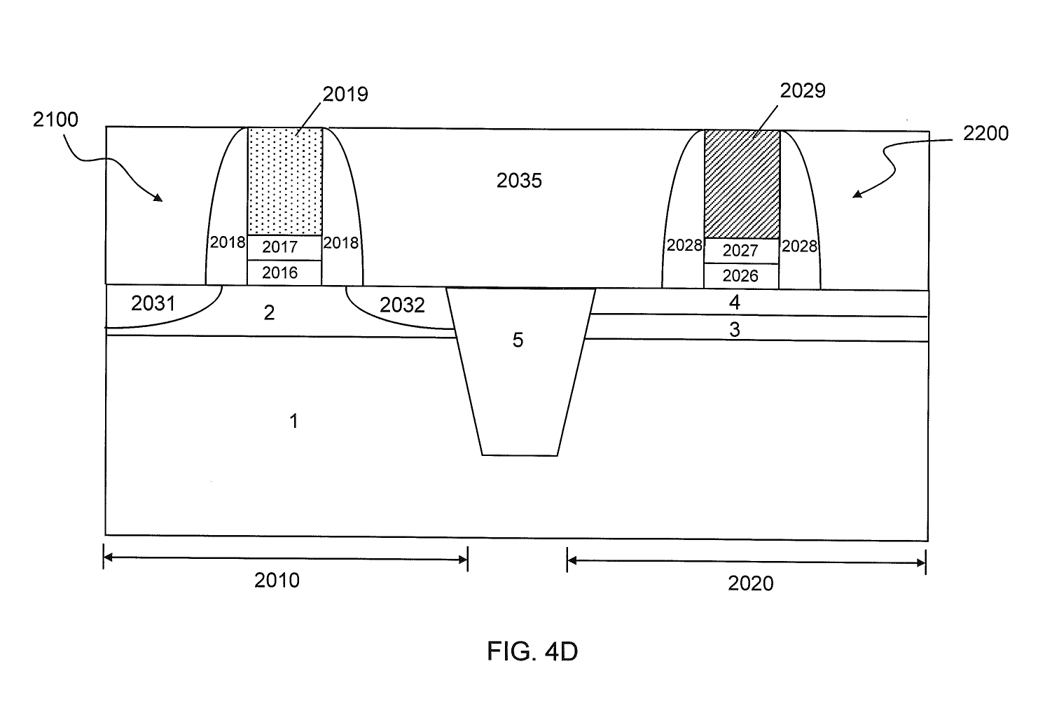

Now referring to FIGS. 1 and 4A-4D, FIGS. 1 and 4A-4D are schematic cross-sectional views illustrating an exemplary complementary transistor pair comprising a p-type FET 2100 and an n-type FET 2200 according to yet another embodiment of the present invention and method for manufacturing such transistor pair. The method for manufacturing the complementary transistor pair shown in FIGS. 1 and 4A-4D is also a gate-last high-k first process for manufacturing high-k dielectric metal-gate transistors. First, a substrate 1 comprising a predetermined region 2010 for forming the p-type FET 2100 and a predetermined region 2020 for forming the n-type FET 2200 with the germanium-containing channel layer 2 in the predetermined region 2010 on the substrate 1 and the optional insulting layer 3 and the metal oxide channel layer 4 in the predetermined region 2020 on the substrate 1 is provided similar to the cross-sectional view shown in FIG. 1. The predetermined regions 1010 and 1020 are the same as the predetermined regions 10 and 20 of FIG. 1. The germanium-containing channel layer 2, the optional insulting layer 3, and the metal oxide channel layer 4 are the same as the ones shown in FIG. 1 and their descriptions are omitted. Before or after formations of the germanium-containing channel layer 2, the optional insulting layer 3, and the metal oxide channel layer 4, a shallow trench isolation structure 5 is formed between the predetermined regions 2010 and 2020 to electrically isolate the p-type FET 2100 and the n-type FET 2200 to be formed. Then, a dummy gate stack comprising an optional interfacial layer 2016, a gate dielectric layer 2017, and a dummy gate electrode 2039 for the p-type FET 1100, and a dummy gate stack (not fully shown) comprising an optional interfacial layer 2026, a gate dielectric layer 2027, and a dummy gate electrode (not shown) for the n-type FET 2200 are formed in the predetermined region 2010 and the predetermined region 2020 respectively as shown in FIG. 4A. The material(s) suitable for the dummy gate electrode 2039 for the p-type FET 2100 and the dummy gate electrode (not shown) for the n-type FET 2200 is addressed with reference to FIG. 3A and is omitted here. An optional dielectric hard mask layer such as a silicon nitride layer may be formed on each of the dummy gate electrodes in the dummy gate stacks to facilitate controlling of a later-performed planarization process. The patterning process of the dummy gate stacks are similar to the patterning process of the gate stacks of FIG. 2. Then, the spacers 2018 and the spacers 2028 are formed beside the dummy gate stacks. Before, after or during (if each spacer comprise multiple spacers) forming the spacers 2018 and the spacers 2028, one or more ion implant processes are performed to form lightly doped drains (LDD, not shown in FIG. 4A), and the source 2031 and the drain 2032. As mentioned earlier with reference to FIGS. 1-2, a channel implant process and an extra layer such as a silicide layer may be optionally performed and formed. Afterward, a contact etching stop layer (CESL) such as a silicon nitride layer (not shown) and one or more interlayer dielectric materials (not shown) are formed on the substrate 1 covering the dummy gate stack 2039, the spacers 2018, and the source 2031 and the drain 2032 for the p-type FET 2100, and the dummy gate stack (not fully shown), the spacers 2028, and the metal oxide channel layer 4 for the n-type FET 2200. Next, a planarization process such as a chemical mechanical polishing process is performed using the optional dielectric hard mask layers (if exist) of the dummy gate stacks or the dummy gate electrodes of the dummy gate stacks as polishing stop layer to form the planarized interlayer dielectric layer 2035 and to achieve a global planar surface. Then, one or more etching processes are performed to remove the dielectric hard mask layer (if used) and the dummy gate electrode for one of the p-type FET 2100 and the n-type FET 2200 (for example the n-type FET 2200 in this case) while the dielectric hard mask layer (if used) and the dummy gate electrode for the other one of the p-type FET 2100 and the n-type FET 2200 (for example the p-type FET 2100 in this case) are protected by a protective layer such as a patterned photoresist layer covering the predetermined region so as to form a gate trench (for example the gate trench 2020T) for the one of the p-type FET 2100 and the n-type FET 2200 as shown in FIG. 4A. Then, the protective layer is removed. Next, an optional bottom barrier layer (not shown), a work-function tuning layer (not shown, for example an n-type work-function tuning layer in this case), an optional top barrier layer (not shown), an optional wetting layer are conformally and blanketly formed on the substrate 1 and in the gate trench just formed (for example the gate trench 2020T in this case) lining sidewalls and bottoms of the gate trench. Then, a bulk low-resistivity conductive layer (not shown) is formed on the substrate 1 filling in the rest space of the gate trench (for example the gate trench 2020T in this case), and one or more planarization processes such as one or more chemical mechanical polishing processes are performed to remove material layers outside the gate trench on the planarized interlayer dielectric layer 2035 and on the dummy gate electrode (the dummy gate electrode 2039 in this case) to achieve a global surface and to form a metal gate electrode (for example the metal electrode 2029 in this case) as shown in FIG. 4B. Now one of the p-type FET 2100 and the n-type FET 2200 (for example the n-type FET 2200 in this case) is completed.

After one of the p-type FET 2100 and the n-type FET 2200 is completed (for example the n-type FET 2200 in this case), one or more etching processes are performed to remove the dielectric hard mask layer (if used) and the dummy gate electrode for the other one of the p-type FET 2100 and the n-type FET 2200 (for example the p-type FET 2100 in this case) while the metal gate electrode for the one of the p-type FET 2100 and the n-type FET 2200 (for example metal gate electrode 2029 for the n-type FET 2200 in this case) is protected by a protective layer such as a patterned photoresist layer covering the predetermined region so as to form a gate trench (for example the gate trench 2010T in this case) for the other one of the p-type FET 2100 and the n-type FET 2200 as shown in FIG. 4C. Then, the protective layer is removed. Next, an optional bottom barrier layer (not shown), a work-function tuning layer (not shown, for example an p-type work-function tuning layer in this case), an optional top barrier layer (not shown), an optional wetting layer are conformally and blanketly formed on the substrate 1 and in the gate trench just formed (for example the gate trench 2010T in this case) lining sidewalls and bottoms of the gate trench. Then, a bulk low-resistivity conductive layer (not shown) is formed on the substrate 1 filling in the rest space of the gate trench (for example the gate trench 2010T in this case), and one or more planarization processes such as one or more chemical mechanical polishing processes are performed to remove material layers outside the gate trench on the planarized interlayer dielectric layer 2035 and on the metal gate electrode (the metal gate electrode 2029 in this case) to achieve a global surface and to form a metal gate electrode (for example the metal electrode 2019 in this case) as shown in FIG. 4D. Now the other one of the p-type FET 2100 and the n-type FET 2200 (for example the p-type FET 2100 in this case) is also completed. It is worth mentioning that the gate trench 2010T for the p-type FET 2100 may be formed and filled before the gate trench 2020T for the n-type FET 2200 is formed and filled.

The methods for manufacturing a complementary transistor pair shown in FIGS. 1 and 3A-3B and FIGS. 1 and 4A-4D are both gate-last high-k first methods for manufacturing high-k dielectric metal-gate transistors. It is more difficult for the method shown in FIG. 3A-3B to tune work-functions for n-type FET and p-type FET respectively because both trenches are formed simultaneously and layers formed in the trench for one of the n-type FET and p-type FET are also formed in the trench for the other one of the n-type FET and p-type FET. Tuning work-functions it is easier for the method shown in FIGS. 4A-4D because the n-type FET and the p-type FET are formed separately, but doing so also makes this method more complex.

Now referring to FIG. 5, FIG. 5 is a schematic cross-sectional view illustrating an exemplary complementary transistor pair comprising the p-type FET 3100 and the n-type FET 3200 according to yet another embodiment of the present invention, wherein the high-k (high dielectric constant) gate dielectric layer 3017 for p-type FET 3100 and the high-k gate dielectric layer 3027 for n-type FET 3200 formed in gate trenches are U-shaped as shown in FIG. 5 not linear shaped as the ones shown in FIGS. 3B and 4D. The complementary transistor pair comprising the p-type FET 3100 and the n-type FET 3200 can be obtained by modifying the method shown in FIGS. 1 and 3A-3B or modifying the method shown in FIGS. 1 and 4A-4D. Specifically, for method shown in FIGS. 1 and 3A-3B and for method shown in FIGS. 1 and 4A-4D, each of the dummy gate stacks formed in two predetermined regions comprises an optional interfacial layer, a gate dielectric layer such as a high-k dielectric layer, and a dummy gate electrode. However, for methods to manufacture the transistor pair comprising the p-type FET 3100 and the n-type FET 3200 shown in FIG. 5, each of the dummy gate stacks formed in two predetermined regions only comprises an optional interfacial layer and a dummy gate electrode, and the gate dielectric layer such as a high-k gate dielectric layer (3017 or 3027) is formed in each gate trench lining sidewalls and bottom of the gate trench after formation of the gate trench and before formation of the metal gate electrode. Forming the high-k gate dielectric layer after formation of gate trenches in the high-k last process may prevent the high-k gate dielectric layer from going through high temperature thermal processes such as source/drain annealing process and prevent the high-k gate dielectric layer from exposing to detrimental cleaning agents or process gases, thereby prevent degradation of the high-k gate dielectric layer. Due to this sequence change, the film stack of the metal gate electrode may change. Furthermore, the optional interfacial layer may also be formed after trench formation to be U-shaped like the U-shaped high-k gate dielectric layer.

Now referring to FIGS. 6A-6B, FIGS. 6A-6B are schematic cross-sectional views illustrating an exemplary complementary fin-type transistor pair comprising the p-type fin-type FET (FinFET) 4100 and the n-type FinFET 4200 according to an embodiment of the present invention and method for manufacturing such fin-type transistor pair. As shown in FIG. 6B, the p-type FinFET 4100 located in a predetermined region 4010 comprises a substrate 4001 comprising a fin A, a germanium-containing channel layer 4002 on the fin A, an optional interfacial layer (not shown) on the germanium containing channel layer 4002, a gate dielectric layer 4017 such as a high-k dielectric layer interposed between a metal gate electrode 4019 and the germanium-containing layer 4002, and the gate electrode 4019. The substrate 4001 is similar to the substrate 1 except the substrate 4001 comprises protruded fin-shaped features such as the fin A for the p-type FinFET 4100 and a fin B for the n-type FinFET 4200. The fin A extends along a direction into the paper (perpendicular to the paper). The germanium-containing channel layer 4002, the optional interfacial layer (not shown) and the gate dielectric layer 4017 are similar to the germanium-containing channel layer 2, the optional interfacial layer 16, and the gate dielectric layer 17 respectively and all straddle on the fin A. The metal gate electrode 4019 is similar to the metal gate electrode 19 and extends along a direction parallel to the paper (perpendicular to the extending direction of the fin A and the fin B). As shown in FIG. 6B, the n-type FinFET 4200 located in a predetermined region 4020 comprises the substrate 4001 comprising a fin B, an optional insulating layer 4003 on the fin B, a metal oxide channel layer 4004 on the optional insulating layer 4003, an optional interfacial layer (not shown) on the metal oxide channel layer 4004, a gate dielectric layer 4027 such as a high-k dielectric layer interposed between a metal gate electrode 4029 and the metal oxide channel layer 4004, and the gate electrode 4029. The fin B extends along a direction into the paper (perpendicular to the paper). The optional insulating layer 4003, the metal oxide channel layer 4004, the optional interfacial layer (not shown), and the gate dielectric layer 4027 are similar to the optional insulating layer 3, the metal oxide channel layer 4, the optional interfacial layer 26, and the gate dielectric layer 4027 respectively. The gate electrode 4029 is similar to the gate electrode 29 and extends in a direction parallel to the paper (perpendicular to the extending direction of fin A and fin B). Transistors formed using fins are electrically insulated by trench isolation structures 4005. In a case (such as this embodiment) where the top surface portion and two sidewall portions of a fin are all channel regions of a transistor, the transistor is called a triple-gate FinFET. In another case where the top surface portion of a fin is covered by a dielectric mask hence isn't a channel region while two sidewall portions of the fin are both channel regions of a transistor, the transistor is called a double-gate FinFET. The metal oxide channel layer of the present invention is preferably applied to the triple-gate FinFET in stead of double-gate FinFET.

Now referring to FIGS. 6A and 6B, in order to fabricate the complementary transistor pair comprising the p-type FinFET 4100 and the n-type FinFET 4200, a method for manufacturing a complementary fin-type transistor pair is disclosed. First, a substrate 4001 comprising a predetermined region 4010 for forming the p-type FinFET 4100 and a predetermined region 4020 for forming the n-type FET 4200 with protruded fin A and fin B is provided as shown in FIG. 1. The fin A and the fin B are formed by for example sidewall image transfer (SIT) technique and/or double patterning technique. One or more insulating films including a insulating film formed by flowable chemical vapor deposition process are formed filling the trenches between the protruded fins such as fin A and fin B, and one or more planarization processes such as chemical mechanical polishing processes are performed on the insulating films to form a global planar surface (upper surfaces of the fins are substantially co-planar with upper surfaces of the planarized insulating films). Then, one or more etching processes are performed to lower the insulating films to a controlled level and to expose the protruded fins. At this stage, the trench isolation structures 4005 are completed. Next, the germanium-containing channel layer 4002 is formed on the fin A, and the optional insulting layer 4003 and the metal oxide channel layer 4004 are formed on fin B as shown in FIG. 6A. The processes to provide different channel layers on different fins may involve blanket growth and partially removal of a film or selective growth of a film. Afterward, replacement gate processes such as the replacement gate processes forming gate trenches simultaneously shown in FIGS. 3A-3B or the replacement gate processes forming gate trenches separately shown in FIGS. 4A-4D are performed. For example, dummy gate stacks (not shown) comprising at least dummy gate electrodes (not shown) are formed on the fins and the trench isolation structures 4005. Spacers (not shown) are formed beside the fins. Then, optional lightly doped drains, and sources and drains (not shown) are formed in the fins by implant processes and/or plasma doping processes. Next, a contact etching stop layer (CESL) such as a silicon nitride layer (not shown) and one or more interlayer dielectric materials (not shown) are formed covering the dummy gate stacks, the spacers, and the sources and the drains, and a planarization process such as a chemical mechanical polishing process is performed on the interlayer dielectric materials to achieve a planarized interlayer dielectric layer (not shown) exposing the dummy gate stacks. Then, one or more etching processes are performed to remove the dummy gate electrodes so as to form gate trenches (not shown). Eventually, a high-k gate dielectric layer and metal gate materials are formed in gate trenches to become the high-k gate dielectric layer 4017 and the metal gate electrode 4019 for the p-type FinFET 4100 and the high-k gate dielectric layer 4027 and the metal gate electrode 4029 for the n-type FinFET 4200. At this stage, the complementary fin-type transistor pair comprising the p-type FinFET 4100 and the n-type FinFET 4200 are completed. It is noted that fin-type transistors are more advanced than high-k dielectric metal-gate transistors, so fin-type transistors are usually formed with gate-last high-k last method.

Now referring to FIGS. 7A-7B, FIGS. 7A-7B are schematic cross-sectional views illustrating an exemplary complementary fin-type transistor pair comprising the p-type fin-type FET (FinFET) 5100 and the n-type FinFET 5200 according to another embodiment of the present invention and method for manufacturing such fin-type transistor pair. The differences between this embodiment shown in FIGS. 7A-7B and previous embodiment shown in FIGS. 6A-6B are the germanium-containing channel layer, the optional insulating layer, and metal oxide channel layer. In the previous embodiment, the germanium-containing channel layer 4002, the optional insulating layer 4003, and metal oxide channel layer 4004 are formed after formations of fins A and B and after formations of trench isolation structures 4005, so they straddle on fins A and B and above the trench isolation structures 4005. In this embodiment, the germanium-containing channel layer 5002, the optional insulating layer 5003, and metal oxide channel layer 5004 are formed after formations of fins A′ and B′ but before formations of trench isolation structures 5005, so they straddle on fins A′ and B′ and part of them are under the trench isolation structures 4005.

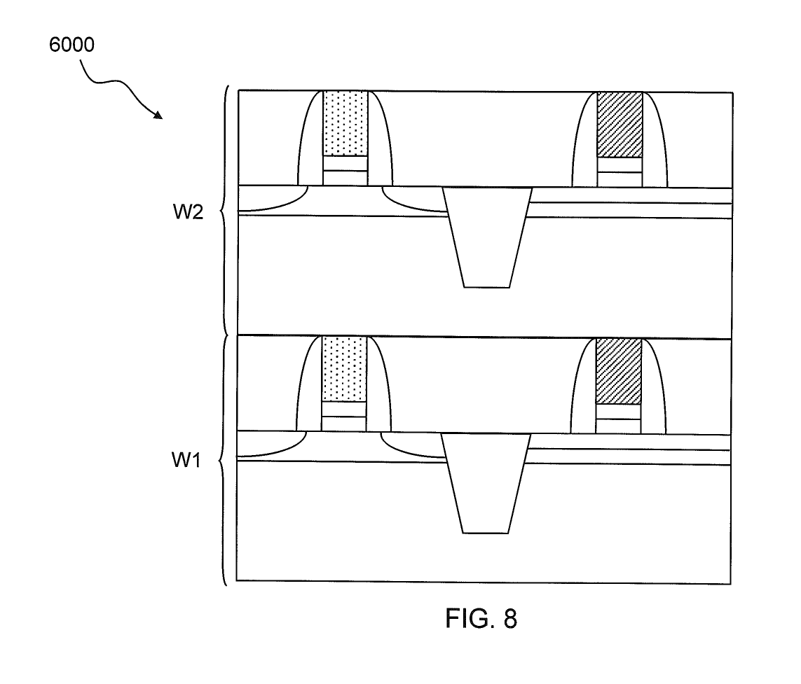

Now referring to FIG. 8, FIG. 8 is a schematic cross-sectional view illustrating a three-dimensional integrated scheme 6000 according to an embodiment of the present invention. The three-dimensional integrated scheme 6000 may comprise multiple device layers W1-Wn stacked vertically and electrically connected by through substrate vias (not shown) or other means, wherein n is equivalent to or larger than 2. Although FIG. 8 only shows W1 and W2, each of the device layers W1-Wn may be one of the substrates shown in FIGS. 2, 3B, 4D, 5, 6B, 7B with the complementary transistor pair of the present invention thereon after being processed such as being thinned and/or having through substrate vias (not shown) formed in them. That is, each one of device layers W1-Wn at least comprises a p-type HKMG FET using a germanium-containing channel layer and an n-type HKMG FET using an ultra-thin metal oxide channel layer, wherein the ultra-thin metal oxide channel layer has a thickness less than a threshold value allowing such ultra-thin metal oxide channel layer to exhibit pinch-off behavior in transfer characteristics and to have a mobility trend without saturation region. With a thickness less than such threshold value, the metal oxide channel layer has a conductivity less than a upper threshold value to have proper pinch off behavior and more than a lower threshold value to be semi-conductive in stead of insulating. For the three-dimensional integrated scheme 6000, the lowest device layer W1 may use any substrate such as a Si substrate having a germanium-containing channel layer epitaxially grown thereon or formed by smart cut or a substrate with a dielectric upper surface having a germanium-containing channel layer formed by smart cut, and the rest of the device layers W2-Wn preferable use a dielectric substrates or a substrate with a dielectric upper surface. The method for manufacturing the three-dimensional integrated scheme 6000 may for example involve: providing at least two of the substrates selected from the substrates shown in FIGS. 2, 3B, 4D, 5, 6B, 7B with the complementary transistor pair of the present invention thereon; optionally thinning the at least two substrates using polishing, plasma or any dry etching, and/or wet chemical etching; before or after optionally thinning the at least two substrates, forming conductive through substrate vias penetrating substrate especially copper through substrate vias in the at least two substrates; stacking the at least two substrates and electrically connecting the at least two substrates by fusion bonding, oxide-to-oxide bonding, copper-to-copper bonding, solder balls, copper pillars, etc.; and cutting the bonded structure comprising the at least two substrates into smaller units. The device layers W1-Wn are defined as the optionally thinned substrates with the formed conductive through substrate vias and the complementary transistor pair of the present invention. It is worth mentioning that the at least two substrates may be stacked after they are cut into chips and in this case the step of cutting the bonded structure is omitted and a step of cutting the at least two substrates individually is inserted after the step of forming conductive through substrate vias.

The ultra-thin metal oxide channel layer of the present invention enhances electrical performance of n-type FET dramatically because being able to be fully depleted allows the majority carriers (electrons) to flow near the interface between the fully depleted ultra-thin metal oxide channel layer and the dielectric layer (the optional interfacial layer and the gate dielectric layer) adjacent to it. Without being scattered in the bulk metal oxide channel layer, electrons reach an unreported high level of mobility 147 cm²/Vs. For a planar (two dimensional) n-type HKMG FET such as the n-type FET shown in FIGS. 2, 3B, 4D and 5, such an ultra-thin metal oxide channel layer would make them compatible with the next generation vertical (three dimensional) n-type fin-type FET in terms of their electrical performances due to fully depletion of such an ultra-thin metal oxide channel during transistor operation. For a three dimensional n-type fin-type FET such as the n-type FinFET shown in FIGS. 6B and 7B, such an ultra-thin metal oxide channel layer would further improve their electrical performances. Although, only HKMG FETs and FinFETs are shown in this disclosure as exemplary examples, the ultra-thin metal oxide channel layer may be applied to any field effect transistors. For example, a p-type FinFET with an epitaxially grown germanium fin and an n-type FinFET with a metal oxide fin formed by evaporation also falls into the scope of the present invention. For example, transistor using nano-wire may also use the ultra-thin metal oxide channel layer.

While the invention has been described in terms of what is presently considered to be the most practical and preferred embodiments, it is to be understood that the invention needs not be limited to the disclosed embodiment. On the contrary, it is intended to cover various modifications and similar arrangements included within the spirit and scope of the appended claims which are to be accorded with the broadest interpretation so as to encompass all such modifications and similar structures.

1. A complementary transistor pair comprising:
an n-type enhancement-mode field effect transistor using a metal oxide channel layer comprising a material selected from SnO₂, ITO, ZnO, and In₂O₃; and
a p-type field effect transistor using a germanium-containing channel layer,
wherein the metal oxide channel layer has a conductivity less than an upper threshold value to have proper pinch off behavior in transfer characteristics and more than a lower threshold value to be semi-conductive.

2. The complementary transistor pair of claim 1, wherein the metal oxide channel layer is at amorphous state or nano-crystalline state.

3. The complementary transistor pair of claim 1, wherein the metal oxide channel layer has a thickness less than a threshold value, and having the thickness less than the threshold value the metal oxide channel layer exhibits pinch-off behavior in transfer characteristics and has a mobility trend without saturation under positive operational voltage.

4. The complementary transistor of claim 3, wherein the metal oxide channel layer comprises SnO₂ and the threshold value is 10 nm.

5. (canceled)

6. The complementary transistor of claim 1, wherein the upper threshold value is 10⁵ S/m and the lower threshold value is 1 S/m.

7. The complementary transistor of claim 6, wherein the metal oxide channel layer comprises SnO₂ having a conductivity of 1.7×10⁵ S/m.

8. The complementary transistor pair of claim 1, wherein the n-type enhancement-mode field effect transistor and the p-type field effect transistor are both fin-type field effect transistors.

9. The complementary transistor pair of claim 1, wherein the n-type enhancement-mode field effect transistor and the p-type field effect transistor are both planar field effect transistors.

10. The complementary transistor pair of claim 9, wherein the n-type enhancement-mode field effect transistor comprises a high-k gate dielectric layer and a metal gate.

11. The complementary transistor pair of claim 10, wherein the metal gate comprises a linear shaped work-function tuning layer.

12. The complementary transistor pair of claim 11, wherein the high-k gate dielectric layer is a linear shaped high-k gate dielectric layer.

13. The complementary transistor pair of claim 10, wherein the metal gate comprises a U-shaped work-function tuning layer.

14. The complementary transistor pair of claim 13, wherein the high-k gate dielectric layer is a U-shaped high-k gate dielectric layer.

15. A three-dimensional integrated scheme comprising:
multiple device layers stacked vertically and electrically connected, each of the multiple device layers comprising:
an n-type enhancement-mode field effect transistor using a metal oxide channel layer comprising a material selected from SnO₂, ITO, ZnO, and In₂O₃; and
a p-type field effect transistor using a germanium-containing channel layer,
wherein the metal oxide channel layer has a thickness less than a threshold value and with such thickness the metal oxide channel layer exhibits pinch-off behavior in transfer characteristics and has a mobility trend without saturation under positive operational voltage.

16. (canceled)

17. The complementary transistor of claim 15, wherein the metal oxide channel layer comprises SnO₂ and the threshold value is 10 nm.

18. The three-dimensional integrated scheme of claim 15, wherein the metal oxide channel layer is at amorphous state or nano-crystalline state.

19. The three-dimensional integrated scheme of claim 15, wherein the metal oxide channel layer has a conductivity less than an upper threshold value to have proper pinch off behavior in transfer characteristics and more than a lower threshold value to be semi-conductive.

20. The three-dimensional integrated scheme of claim 19, wherein the upper threshold value is 10⁵ S/m and the lower threshold value is 1 S/m.

21. The three-dimensional integrated scheme of claim 20, wherein the metal oxide channel layer comprises SnO₂ having a conductivity of 1.7×10⁵ S/m.

22. The three-dimensional integrated scheme of claim 15, wherein the n-type enhancement-mode field effect transistor and the p-type field effect transistor are both fin-type field effect transistors.

23. The three-dimensional integrated scheme of claim 15, wherein the the n-type enhancement-mode field effect transistor and the p-type field effect transistor are both planar field effect transistors.

24. The three-dimensional integrated scheme of claim 23, wherein the n-type enhancement-mode field effect transistor comprises a high-k gate dielectric layer and a metal gate.

25. The three-dimensional integrated scheme of claim 24, wherein the metal gate comprises a linear shaped work-function tuning layer and the high-k gate dielectric layer is linear shaped.

26. The three-dimensional integrated scheme of claim 24, wherein the metal gate comprises a U-shaped work-function tuning layer and the high-k gate dielectric layer is U-shaped.
